(19) United States
(12) Patent Application Publication
(10) Pub. No.: US 2005/0073059 A1
(43) Pub. Date: Apr. 7, 2005

(54) Integrated circuit with dual electrical attachment PAD configuration

(76) Inventor: James Frank Caruba, Bartlett, IL (US)

Correspondence Address: SIEMENS CORPORATION;INTELLECTUAL PROPERTY DEPARTMENT, 170 WOOD AVENUE SOUTH, ISELIN, NJ, 08830, US

(21) Appl. No.: 10/953,543

(22) Filed: Sep. 29, 2004

Related U.S. Application Data
(60) Provisional application No. 60/506,835, filed on Sep. 29, 2003.

(51) Int. Cl. H01L 23/48; H01L 21/44

(52) U.S. Cl. 257/786; 438/612

(57) ABSTRACT

According to the present invention, an integrated circuit has a terminal pad configuration such that the integrated circuit may be wire bonded or flip chip bonded. The terminal pad configuration uses a staggered rows of pads to allow the different bonding.

### FIELD OF THE INVENTION

The present invention deals with the packaging and mounting of integrated circuits (ICs) in general, and the specific geometries of an ICs' electrical interconnections in particular.

### BACKGROUND

An IC must be connected to other electronic devices by interconnections. Packaging is the term of art for the bridge that interconnects an IC into a system of other components to form an electronic product.

An interconnection is the conductive path required to achieve connection from one circuit element to another or to the rest of the circuit system. Such interconnections may be pins, terminals, formed conductors, or any other mating system. The interface between a chip terminal and an interconnect is done through what is called a ‘pad,’ which is an enlarged conducting area on the chip surface created for the purpose of bonding an external interconnect to a chip terminal. The bonding pitch is the nominal distance between the centers of adjacent pads. A bare die can be packaged using a number of packaging types depending on the required number of I/O terminals, thermal properties, size, etc. Moreover, a number of interconnection technologies such as wire bonding and flip-chip bonding technologies can also be used, depending on the requirements.

Packaging an IC often includes mounting the IC on a substrate. The substrate will have the appropriate electrical interconnects to the IC, and itself can be mounted into a system. This substrate may be a ceramic such as alumina (Al₂O₃), beryllia (BeO), or glass-ceramic. The ceramic substrate has a number of advantageous characteristics. Ceramic substrate is an electrical insulator. Its properties do not change radically with heat. Specifically it has a relatively low thermal coefficient of expansion (TCE). Finally, it imparts mechanical strength to the fragile silicon die.

Another technology for connecting an IC into a system is to mount the silicon die of an IC to a Printed Circuit Board (PCB). Thus the PCB is a substrate for the silicon die. This PCB is typically made of a glass epoxy substance e.g. FR-4. This is a subset of organic substrates which a silicon die may be mounted on. The ability to use to use PCB as a substrate may be less expensive than the use of ceramics.

Ceramics and PCBs have dramatically different coefficients of thermal expansion. Though ceramics are more expensive than PCBs, there are certain application where ceramics are required, because of large area direct attach silicon components. Large area silicon die need the relatively lower TCE of ceramic substrates, as well as the superior mechanical support. However, other applications can use the lower cost alternative of mounting directly to PCBS, because the applications have less stringent thermal expansion and power dissipation requirements (where the lower power dissipation requirement means less heat generated).

When ceramic is used as a substrate for an IC, a “flip-chip” process may typically be used to attach the IC to the ceramic substrate. In contrast, typically a wire bonding process may be used to attach an IC to a PCB substrate.

Wire bonding is a method used of connecting the IC to the substrate via a fine wire. When wire bonding technology is used, the interconnection between the chip and the substrate is performed by connecting the pads on the chip surface to the so called “lead frame” which is simply a rectangular metal frame with leads. After encapsulation or lidding of the package, the frame is cut off, leaving the leads extended from the package.

Flip-chip technology is any technology in which the active surface of the silicon die of the integrated circuit is bonded to the substrate. Generally, some form of solder bump bonding is used. Solder bumps are small spheres of solder (solder balls) that are bonded to contact areas or pads of semiconductor devices and that are subsequently used for face-down bonding. The length of the electrical connections between the chip and the substrate can be minimized by (a) placing solder bumps on the die, (b) flipping the die over, (c) aligning the solder bumps with the contact pads on the substrate, and (d) re-flowing the solder balls in a furnace to establish the bonding between the die and the substrate. Note that in this technology the contact pads are distributed over the entire chip surface rather than being confined to the periphery, as in wire bonding. As a result, the silicon area is used more efficiently, the maximum number of interconnects is increased, and signal interconnections are shortened.

In terms of the design process of complete ICs, the circuit design of the IC itself most be finalized into a mask long before a packaging technology must be chosen. However, currently there is no freedom of choice between packaging technologies once the circuit design is frozen, as the circuit design determines the configuration of pads on the silicon die itself. The configuration of pads needed for wire bonding is different than the configuration of pads for flip-chip mounting.

It would be advantageous to be able to have a single circuit design for a silicon die to be able to be either wire bonded or flip chip mounted, as this would allow a switch between ceramic and PCB substrates without compete circuit redesign. This allows reuse of chip designs and/or the delay of choice of a packaging technology to later in a design cycle.

### SUMMARY

According to the present invention, an integrated circuit has a terminal pad configuration such that the integrated circuit may be wire bonded or flip chip bonded. The terminal pad configuration uses a staggered rows of pads to allow the different bonding.

### BRIEF DESCRIPTION OF THE DRAWINGS

The accompanying drawings, which are incorporated herein and form part of the specification, illustrate various embodiments of the present invention and, together with the description, further serve to explain the principles of the invention and to enable a person skilled in the pertinent art to make and use the invention. In the drawings, like reference numbers indicate identical or functionally similar elements. A more complete appreciation of the invention and many of the attendant advantages thereof will be readily obtained as the same becomes better understood by reference to the following detailed description when considered in connection with the accompanying drawings, wherein:

FIG. 1 is a diagram of a common pad configuration for a wire bonded IC;

FIG. 2 is a diagram of a common pad configuration for a flip mounted IC;

FIG. 3 is an diagram of a pad configuration according to the present invention; and

FIG. 4 is a diagram showing the pad configuration of FIG. 3 overlaid with bonding wires.

### DEATILED DESCRIPTION

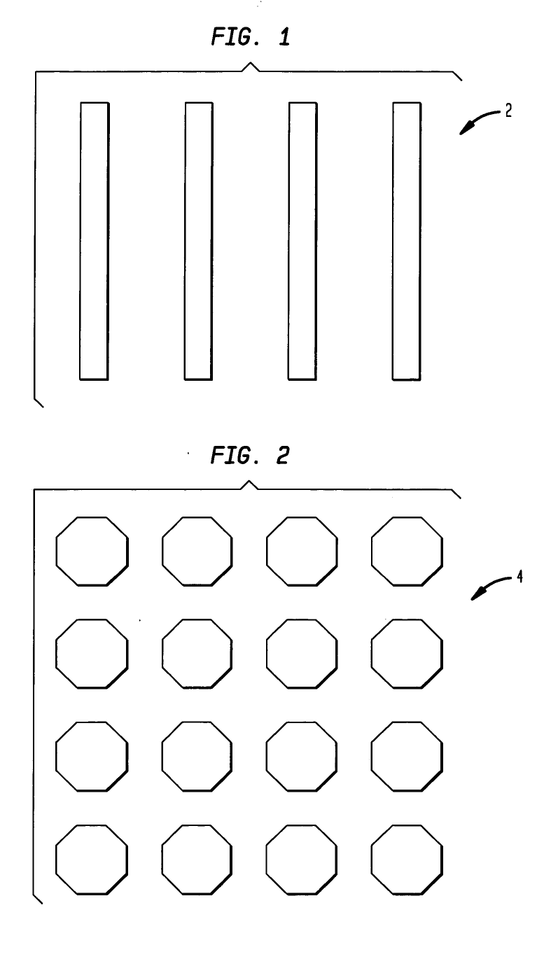

FIG. 1 shows a common pad configuration for an IC to be wire bonded. Note that the wire bonding process has interconnections at the edge, or periphery, only. The fine wires are bonded to the rectangular pads 2 on the IC. The length of the pads allows a greater margin of error in placing the IC.

FIG. 2 shows a common pad configuration for an IC to be flip chip mounted. The grid pattern of pads 4 shows that interconnects are made over the entire area of the IC, not just the periphery.

If an IC with a wire bond pad configuration was attached to a substrate set to receive a flip chip pad configuration, then short circuits would result from multiple contacts on the rectangular pads on the IC. In the reverse, if an IC with a flip chip pad configuration were attached to a substrate set to receive a wire bonding pad configuration, short circuits would again result.

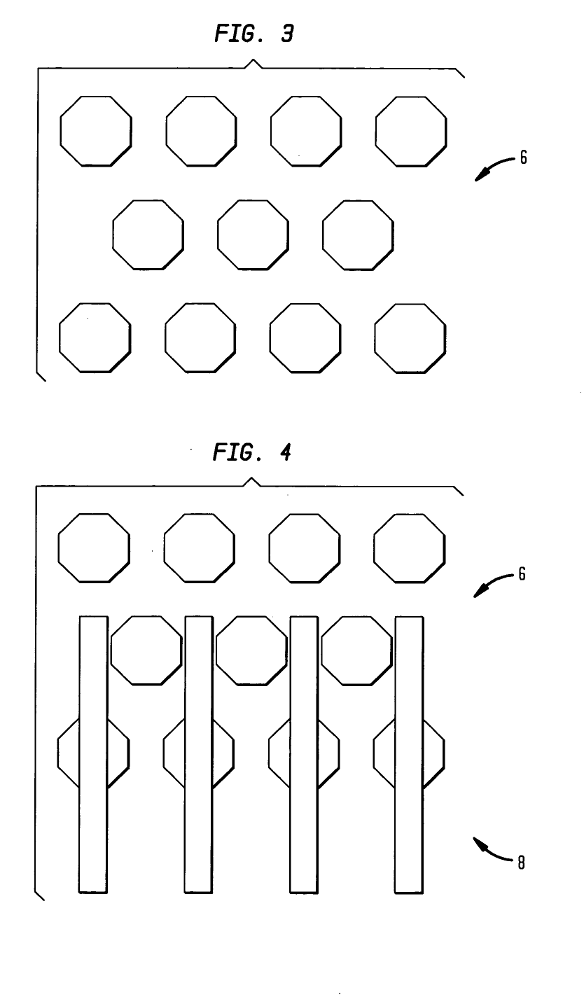

FIG. 3 shows the preferred embodiment of the present invention. A pad configuration for in IC is shown which could be attached to a substrate having either a wire bonding of flip chip pad configuration. The pads 6 in FIG. 3 are arranged in a staggered pattern.

FIG. 4 shows the pads 6 coming in contact with the contacts 8 used in a wire bonding process. It illustrates how the pads 6 can be used in a wire bonding process.

Advantageously, a single IC design can be flip chip attached or wire bonded. Furthermore, this will allow the use of either ceramic or PCB substrates for a single IC design. Moreover, the additional die size needed to implement the dual pad configuration is small.

1. A configuration of terminal pads of an integrated circuit comprising;
a) a first set of terminal pads having a first number of rows of pads, each row having a second number of pads with a fist distance between each individual pads, and the first number of rows of pads having a second distance between each row;
b) a second set of terminal pads having a second number of rows of pads, each row having a third number of pads with a first distance between each individual pads, and the second number of rows of pads having a second distance between each row;
c) wherein the second number of rows are between the first number of rows and are offset by half the second distance from the first number of rows if pads.

2. An integrated circuit comprising circuits and terminal pads attached to said circuits wherein the terminal pads
a) circuits within the integrated circuits;
b) terminal pads electrically connected to said circuits comprising;
i. a first set of terminal pads having a first number of rows of pads, each row having a second number of pads with a fist distance between each individual pads, and the first number of rows of pads having a second distance between each row;
ii. a second set of terminal pads having a second number of rows of pads, each row having a third number of pads with a first distance between each individual pads, and the second number of rows of pads having a second distance between each row;
iii. wherein the second number of rows are between the first number of rows and are offset by half the second distance from the first number of rows if pads.

3. The integrated circuit of claim 2 wherein the integrated circuit is wire bonded to a substrate.

4. The integrated circuit of claim 2 wherein the integrated circuit is flip chip bonded to a substrate.
